(19) United States
(12) Patent Application Publication
(10) Pub. No.: US 2016/0305981 A1
(43) Pub. Date: Oct. 20, 2016

(54) Probe Card

(71) Applicant: MPI Corporation, Zhubei (TW)

(72) Inventors: Wei-Cheng Ku, Zhubei (TW); Jun-Liang Lai, Zhubei (TW); Chih-Hao Ho, Zhubei (TW); Hao Wei, Zhubei (TW)

(73) Assignee: MPI Corporation, Zhubei (TW)

(21) Appl. No.: 15/098,186

(22) Filed: Apr. 13, 2016

(30) Foreign Application Priority Data
Apr. 14, 2015 (TW) 104111919

(51) Int. Cl. G01R 1/073

(52) U.S. Cl. CPC G01R 1/07342

(57) ABSTRACT

A probe card for transmitting power signals from a tester to two devices under test (DUTs) is provided, which includes two signal pins, two power conducting circuits, and at least a matching part. The signal pins are made of conductive materials, wherein one end of the signal pin contacts one of the DUTs. The two power conducting circuits are electrically connected to the two signal pins respectively to transmit the power signals to the DUTs. One of two ends of the power conducting circuits is connected to the signal pins; the other end of the power conducting circuits is electrically connected to the tester. The matching part is electrically connected to the power conducting circuit in parallel to lower a resistance of the power conducting circuit below a predetermined value, or to lower a percentage error of resistance of the power conducting circuit below a predetermined percentage error.

### BACKGROUND OF THE INVENTION

1. Technical Field

The present invention relates generally to a probe card, and more particularly to a probe card which includes power conducting circuits having corresponding resistance.

2. Description of Related Art

Probe card is widely utilized as an interface between a tester and a device under test (DUT) to transmit power signals, which is a common way to detect if every electrical component of the DUT is electrically connected correctly. Additionally, to improve the detecting efficiency, the probe card is connected to more than one DUTs simultaneously.

However, in such cases, if the intensity of the power signals received by the DUTs on the same probe card are different, that is, if said DUTs are tested under distinct test conditions, the test results would be inaccurate.

### BRIEF SUMMARY OF THE INVENTION

In view of the above, the primary objective of the present invention is to provide a probe card which adjusts the DUTs to be tested under almost the same test condition when the probe card is connected to more than one DUTs simultaneously.

The present invention provides a probe card for transmitting power signals from a tester to two devices under test (DUTs), wherein the tester provides power to the DUTs via the power signals, and the DUTs are tested with the power. The probe card includes two signal pins, two power conducting circuits, and at least a matching part. The two signal pins are made of conductive materials, wherein each of the two signal pins has two ends, and one of the two ends thereof contacts one of the DUTs. The two power conducting circuits are electrically connected to the two signal pins respectively to transmit the power signals to the DUTs, wherein each of the two power conducting circuits has two ends, and one of the two ends thereof is connected to the other end of the signal pins; the other end of each of the power conducting circuits is electrically connected to the tester. The at least a matching part is electrically connected to at least one of the power conducting circuits in parallel to lower a resistance of the at least one of the power conducting circuits below a predetermined value.

The present invention further provides a probe card for transmitting power signals from a tester to two devices under test (DUTs), wherein the tester provides power to the DUTs via the power signals, and the DUTs are tested with the power. The probe card includes two signal pins, two power conducting circuits, and at least a matching part. The two signal pins are made of conductive materials, wherein each of the two signal pins has two ends, and one of the two ends thereof contacts one of the DUTs. The two power conducting circuits are electrically connected to the two signal pins respectively to transmit the power signals to the DUTs, wherein each of the two power conducting circuits has two ends, and one of the two ends thereof is connected to the other end of the signal pins; the other end of each of the power conducting circuits is electrically connected to the tester. The at least a matching part is electrically connected to at least one of the power conducting circuits in parallel to lower a percentage error of resistance of the at least one of the power conducting circuits below a predetermined percentage error.

Whereby, with the design of the matching part, the resistance of the power conducting circuit which is electrically connected to the matching part in parallel is lowered effectively, or the resistance of the two power conducting circuits become almost the same. Accordingly, the power signals received by the DUTs via the two power conducting circuits are corresponding, which makes sure that the DUTs are tested under almost the same test condition.

### BRIEF DESCRIPTION OF THE SEVERAL VIEWS OF THE DRAWINGS

The present invention will be best understood by referring to the following detailed description of some illustrative embodiments in conjunction with the accompanying drawings, in which

FIG. 1 is a perspective view of the a first embodiment of the present invention;

FIG. 2 is a partially exploded view of FIG. 1, showing the connecting relation among the matching part, substrate, and the carrier substrate;

FIG. 3 is a schematic diagram of the first embodiment, showing the structure of the probe card;

FIG. 4 is a partial enlarged view of the first embodiment, showing the matching part; and

FIG. 5 is a schematic diagram of a second embodiment, showing another type of fitting the matching part.

### DETAILED DESCRIPTION OF THE INVENTION

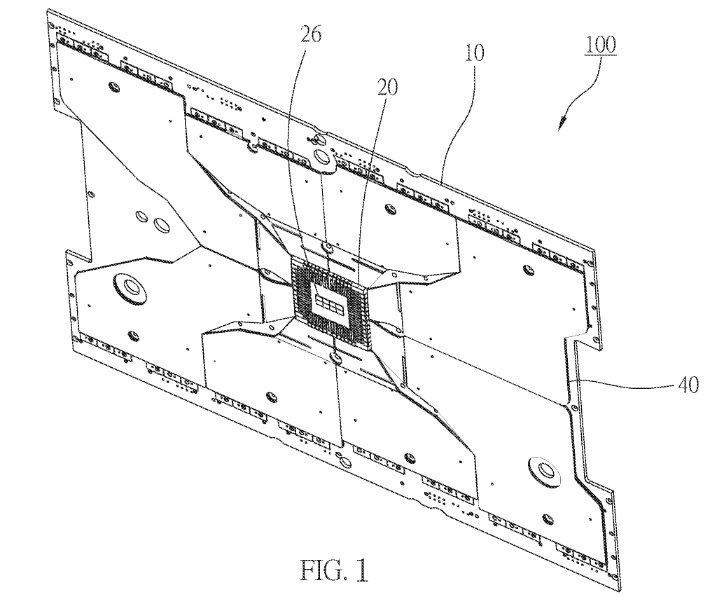

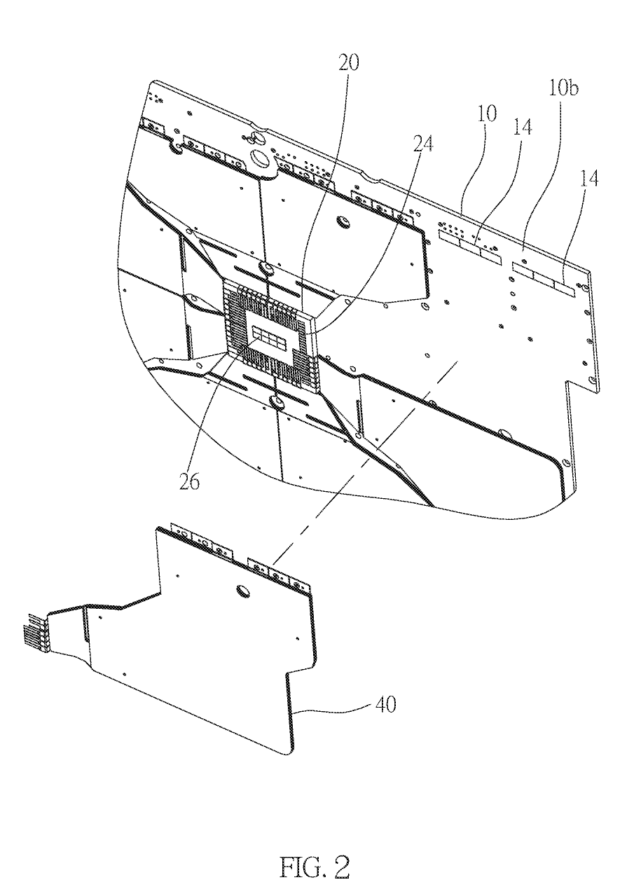

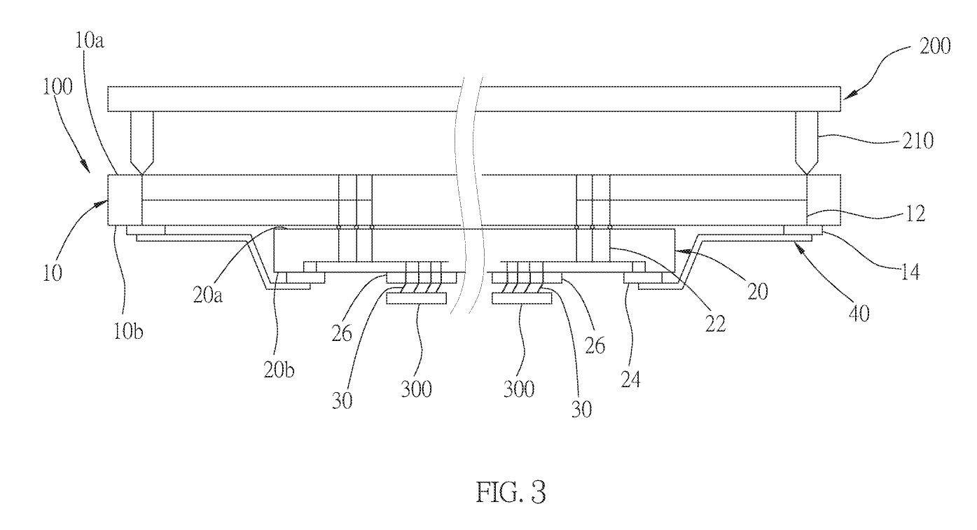

As shown in FIG. 1 to FIG. 3, the probe card 100 is adapted to transmit power signals from power terminals 210 of a tester 200 to a plurality of devices under test (DUTs) 300 respectively, wherein the tester 200 provides power to the DUTs 300 via the power signals, and the DUTs 300 are tested with the power. The probe card 100 includes a substrate 10, a carrier substrate 20, a plurality of signal pins 30, and a plurality of matching parts 40.

The substrate 10 has a surface 10a to be connected to the tester 200. In this embodiment, the substrate 10 is a multilayer printed circuit board including a plurality of first power conductors 12 which are made of conductive materials; each of the first power conductors 12 is connected to one of the power terminals 210. A plurality of signal contacts 14 are provided on another surface 10b of the substrate 10, and each of the signal contacts 14 is electrically connected to the corresponding first power conductor 12.

The carrier substrate 20 has a surface 20a to be connected to and face the surface 10b of the substrate 10. In the embodiment, the carrier substrate 20 is a multi-layer ceramic (MLC) including a plurality of second power conductors 22 which are made of conductive materials; each of the second power conductors 22 is connected to the corresponding first power conductor 12 with one end thereof. A plurality of signal contacts 24 are provided on another surface 20b of the carrier substrate 20, and each of the signal contacts 24 is electrically connected to the corresponding second power conductor 22. Moreover, the carrier substrate 20 includes eight detection zones 26, and each of the detection zones 26 is adapted to be connected to one of the DUTs. Accordingly, the probe card 100 could be connected to the plurality of DUTs 300 simultaneously, and could be adapted to test the DUTs 300.

The signal pins 30 are provided within the detection zones 26, and are made of metal. Each of the signal pins 30 is electrically connected to the second power conductor 22 with one end thereof, and parts to be connected for testing or power supplying with the other end thereof. Additionally, in another embodiment, the signal pins 30 are made of conductive materials instead of metal.

In this sense, the first power conductor 12 of the substrate 10 and the corresponding second power conductor 22 of the carrier substrate 20 are connected in series to form power conducting circuits to transmit power signals from the tester 100 to the DUTs 300 via the signal pins 30.

The matching parts 40 in the embodiment are copper sheets. Each of the copper sheets is electrically connected to the signal contact 14 on the substrate 10 with an end thereof to be electrically connected to the first power conductor 12 and the tester 100, and is electrically connected to the signal contact 24 on the carrier substrate 20 with another end thereof to be electrically connected to the second power conductor 22 and the signal pins 30.

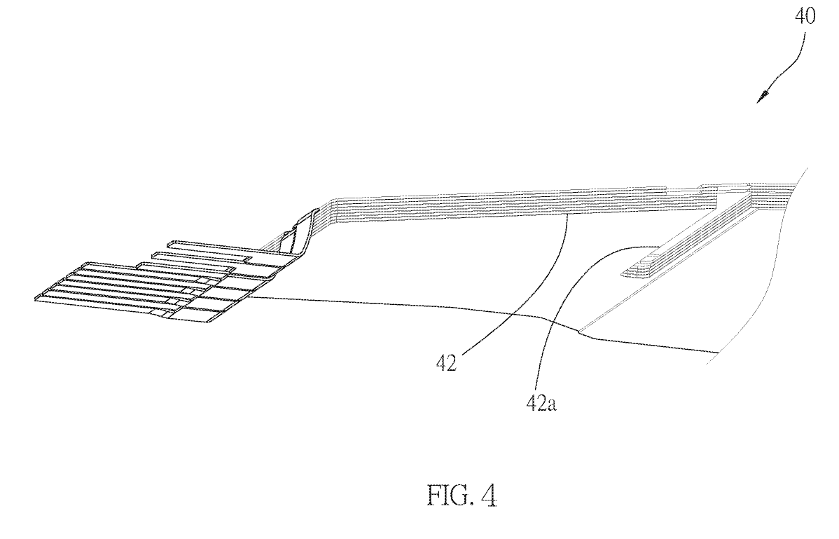

As shown in FIG. 4, the matching part 40 includes a plurality of stacked layers of copper sheets 42, wherein the surface of each layer of the copper sheets 42 is electrically insulated; for example, an insulating layer is provided between two layers of copper sheets 42 (not shown), wherein the insulating layer could be made of insulating film, insulating paint, polytetrafluoroethylene coating, or the like. In this sense, each layer of the copper sheets 42 is connected to the corresponding signal contacts 14 and 24, and is electrically connected to the corresponding power conducting circuits in parallel. In this case, by adjusting the size, the mass, and the shape of the copper sheets 42 which effect the resistance of the copper sheets 42, the resistance of the power conducting circuits could not only be lowered, but also be almost equivalent.

For the explanatory purpose, the DUTs 300 in the embodiment includes the DUT 301 and the DUT 302 as described below.

Both the DUTs 301 and 302 has a plurality of functional blocks for different applications such as CPU, WIC, DMAC, and MCU, wherein each of the functional blocks requires different power signal transmitted from different power conducting circuits. As shown in Table 1 below, before hanging the matching part, the resistance of the power conducting circuits connected to different functional blocks of the DUT 301 or the DUT 302 are distinct. For DUT 301, the resistance of the power conducting circuits transmitting the power signals to CPU, WIC, DMAC, and MCU are 52 mΩ, 30 mΩ, 70 mΩ, and 90 mΩ respectively; For DUT 302, the resistance of the power conducting circuits transmitting the power signals to CPU, WIC, DMAC, and MCU are 40 mΩ, 60 mΩ, 58 mΩ, and 45 mΩ respectively. In other words, even though the initial power signals transmitted from the tester 100 to each of the functional blocks are identical, the power signals finally received by the DUTs 301 and 302 are different, for the initial power signals are attenuated at different levels by different power conducting circuits which have dissimilar resistance. In such case, false testing results would be obtained due to the different power signals received by the same functional blocks in the two DUTs 301 and 302.

For making the power signals received by the DUTs 301 and 302 be equivalent, the resistance of the power conducting circuits connected to different functional blocks have to be calculated first. According to the calculated resistance, the matching parts are adjusted before electrically connected to the power conducting circuits in parallel. Whereby, the resistance of the power conducting circuits are effectively lowered after hanging the matching parts. Additionally, the resistance of the power conducting circuits connected to the same functional blocks is adjusted to be equivalent or even be the same.

The resistance of the power conducting circuits connected to different functional blocks of the DUT 301 or the DUT 302 after hanging the matching part are shown in Table 2. For DUT 301, the resistance of the power conducting circuits transmitting the power signals to CPU, WIC, DMAC, and MCU are 15 mΩ, 10 mΩ, 16 mΩ, and 12 mΩ; For DUT 302, the resistance of the power conducting circuits transmitting the power signals to CPU, WIC, DMAC, and MCU are 15 mΩ, 11 mΩ, 15.9 mΩ, and 11.8 ma Comparing with Table 1, after hanging the matching parts, the resistance of the power conducting circuits are effectively lowered to below a predetermined value, wherein the predetermined value in the embodiment is 20 mg. In addition, the resistance of the power conducting circuits connected to the same functional blocks in the DUTs 301 and 302 are equivalent, or even the same. Therefore, when the probe card is connected to more than one DUTs simultaneously, the intensity of the power signals received by the DUTs on the same probe card are equivalent, which makes the DUTs be tested under distinct test conditions.

TABLE 2
after hanging the matching part

| | |
|---|---|
| functional | resistance of power |
| blocks | conducting circuits |

DUT 301

| | |
|---|---|
| CPU | 15 mΩ |
| WIC | 10 mΩ |
| DMAC | 16 mΩ |
| MCU | 12 mΩ |

DUT 302

| | |
|---|---|
| CPU | 15 mΩ |
| WIC | 11 mΩ |
| DMAC | 15.9 mΩ |
| MCU | 11.8 mΩ |

TABLE 1
before hanging the matching part

| | |
|---|---|
| functional | resistance of power |
| blocks | conducting circuits |

DUT 301

| | |
|---|---|
| CPU | 52 mΩ |
| WIC | 30 mΩ |
| DMAC | 70 mΩ |
| MCU | 90 mΩ |

DUT 302

| | |
|---|---|
| CPU | 40 mΩ |
| WIC | 60 mΩ |
| DMAC | 58 mΩ |
| MCU | 45 mΩ |

Furthermore, each of the copper sheets 42 has at least a notch 42a illustrated in FIG. 4, and the use of the notch 42a is specified below. When the copper sheets 42 are transmitting the power signals to provide electric power to the DUTs 300, a part of the electric power would convert to thermal energy, which causes thermal expansion and contraction of the copper sheets 42. Thus, the notch 42a allows a margin for deforming in the copper sheet 42, and prevents the copper sheet 42 from releasing from the substrate 10 or the carrier substrate 20 because of the thermal expansion and contraction.

In the above embodiment, the matching part 40 is designed to lower the resistance of the power conducting circuits below the predetermined value. However, in another embodiment, the matching part 40 is designed to lower a percentage error of resistance of the power conducting circuits below a predetermined percentage error. For example, without providing any matching part, the resistance of the power conducting circuits transmitting the power signals to different functional blocks in a DUT 303, CPU, WIC, DMAC, and MCU, are 15 mΩ, 18 mΩ, 13 mΩ, and 20 mΩ, while the resistance of the power conducting circuits transmitting the power signals to different functional blocks in a DUT 304, CPU, WIC, DMAC, and MCU, are 30 mΩ, 35 mΩ, 28 mΩ, and 14 mΩ. In such case, the percentage error of resistance of the power conducting circuits according to each functional blocks, CPU, WIC, DMAC, and MCU, between the DUTs 303 and 304, are 100%, 94%, 115%, and 30% respectively. The predetermined percentage error in the embodiment is 10%, so the percentage errors above are quite large. Hence, by connecting the matching part to the power conducting circuits, the resistance of the power conducting circuits transmitting the power signals to different functional blocks in a DUT 303, CPU, WIC, DMAC, and MCU, are modified to 5 mΩ, 6 mΩ, 7 mΩ, and 8 mΩ, while the resistance of the power conducting circuits transmitting the power signals to different functional blocks in a DUT 304, CPU, WIC, DMAC, and MCU, are modified to 5.25 mΩ, 6.3 mΩ, 7.35 mΩ, and 8.4 mΩ. With such modification, the percentage error of resistance of the power conducting circuits according to each functional blocks between the DUTs 303 and 304 are 5%, which is less than the predetermined percentage error 10%.

On the other hand, the matching parts 40 can be made of conductive materials with high conductivity instead of copper sheets practically. Moreover, the copper sheets can be replaced by multi-core stranded wires, flexible printed circuit, or coaxial cables.

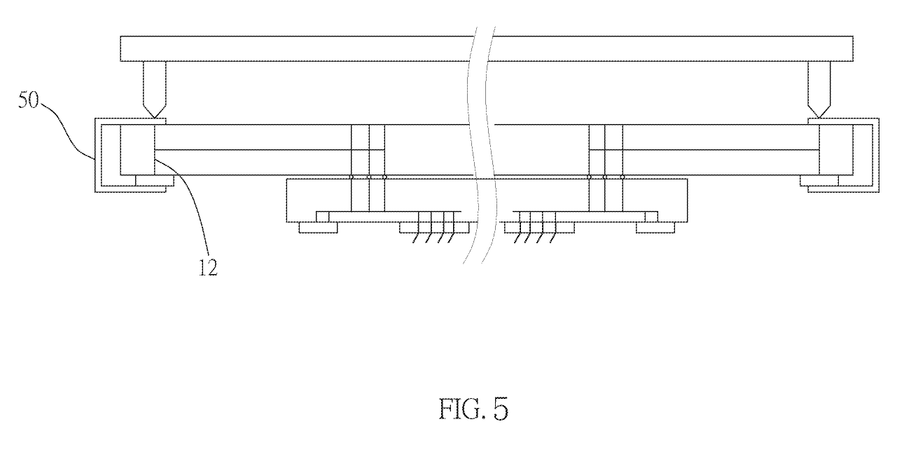

As shown in FIG. 5, in another embodiment, a matching part 50 is electrically connected to the first power conductor 12 in parallel only, to adjust to the resistance of the first power conductor 12.

Additionally, the matching part is selectively connected to the power conducting circuits. For example, a probe card in another embodiment has eight power conducting circuits, wherein the resistance of seven power conducting circuits thereof are equivalent, while the resistance of the rest one power conducting circuit is different from the others. In this case, the matching part is selectively connected to the power conducting circuit with said different resistance such that the resistance of the eight power conducting circuits are adjusted to be equivalent.

On the other hand, the predetermined value is set based on the demand for the DUTs testing, and is not limited to abovementioned 20 mΩ.

Therefore, by the design of the matching parts, the resistance of the power conducting circuits which are electrically connected to the matching parts in parallel is not only effectively lowered, but also equivalent. Whereby, the power signals transmitted from the tester via the power conducting circuits are equivalent such that the DUTs are tested under almost the same test condition.

It must be pointed out that the embodiments described above are only some preferred embodiments of the present invention. All equivalent structures which employ the concepts disclosed in this specification and the appended claims should fall within the scope of the present invention.

What is claimed is:

1. A probe card for transmitting power signals from a tester to two devices under test (DUTs), wherein the tester provides power to the DUTs via the power signals, and the DUTs are tested with the power; the probe card comprising:
two signal pins made of conductive materials, wherein each of the two signal pins has two ends, and one of the two ends thereof contacts one of the DUTs;
two power conducting circuits electrically connected to the two signal pins respectively to transmit the power signals to the DUTs, wherein each of the two power conducting circuits has two ends, and one of the two ends thereof is connected to the other end of the signal pins; the other end of each of the power conducting circuits is electrically connected to the tester; and
at least a matching part electrically connected to at least one of the power conducting circuits in parallel to lower a resistance of the at least one of the power conducting circuits below a predetermined value.

2. The probe card of claim 1, further comprising a substrate connected to the tester, wherein the power conducting circuit further comprises at least one first power conductor which is provided in the substrate.

3. The probe card of claim 2, further comprising a carrier substrate connected to the substrate, wherein the power conducting circuit further comprises at least one second power conductor provided in the carrier substrate, and the second power conductor and the first power conductor are connected in series; the matching part is electrically connected to the first power conductor with one end thereof, and is electrically connected to the second power conductor with another end thereof.

4. The probe card of claim 1, wherein the matching part comprises a copper, which is electrically connected to the tester with one end thereof, and is electrically connected to a corresponding signal pin with another end thereof.

5. The probe card of claim 4, wherein the matching part comprises a plurality of stacked layers of copper and a plurality of insulating layers provided between two of the layers of copper to insulate the layers of copper; each of the layers of copper is electrically connected to the tester with one end thereof, and is electrically connected to a corresponding signal pin with another end thereof.

6. The probe card of claim 4, wherein the copper has at least a notch.

7. The probe card of claim 1, wherein the matching part comprises a multi-core stranded wire, a flexible printed circuit, or a coaxial cable, which is electrically connected to the tester with one end thereof, and is electrically connected to a corresponding signal pin with another end thereof.

8. A probe card for transmitting power signals from a tester to two devices under test (DUTs), wherein the tester provides power to the DUTs via the power signals, and the DUTs are tested with the power; the probe card comprising:
two signal pins made of conductive materials, wherein each of the two signal pins has two ends, and one of the two ends thereof contacts one of the DUTs;
two power conducting circuits electrically connected to the two signal pins respectively to transmit the power signals to the DUTs, wherein each of the two power conducting circuits has two ends, and one of the two ends thereof is connected to the other end of the signal pins; the other end of each of the power conducting circuits is electrically connected to the tester; and
at least a matching part electrically connected to at least one of the power conducting circuits in parallel to lower a percentage error of resistance of the at least one of the power conducting circuits below a predetermined percentage error.

9. The probe card of claim 8, further comprising a substrate connected to the tester, wherein the power conducting circuit further comprises at least one first power conductor which is provided in the substrate.

10. The probe card of claim 9, further comprising a carrier substrate connected to the substrate, wherein the power conducting circuit further comprises at least one second power conductor provided in the carrier substrate, and the second power conductor and the first power conductor are connected in series; the matching part is electrically connected to the first power conductor with one end thereof, and is electrically connected to the second power conductor with another end thereof.

11. The probe card of claim 8, wherein the matching part comprises a copper, which is electrically connected to the tester with one end thereof, and is electrically connected to a corresponding signal pin with another end thereof.

12. The probe card of claim 9, wherein the matching part comprises a copper, which is electrically connected to the tester with one end thereof, and is electrically connected to a corresponding signal pin with another end thereof.

13. The probe card of claim 10, wherein the matching part comprises a copper, which is electrically connected to the tester with the one end thereof, and is electrically connected to a corresponding signal pin with the another end thereof.

14. The probe card of claim 11, wherein the matching part comprises a plurality of stacked layers of copper and a plurality of insulating layers provided between two of the layers of copper to insulate the layers of copper; each of the layers of copper is electrically connected to the tester with one end thereof, and is electrically connected to a corresponding signal pin with another end thereof.

15. The probe card of claim 11, wherein the copper has at least a notch.

16. The probe card of claim 8, wherein the matching part comprises a multi-core stranded wire, a flexible printed circuit, or a coaxial cable, which is electrically connected to the tester with one end thereof, and is electrically connected to a corresponding signal pin with another end thereof.

17. The probe card of claim 9, wherein the matching part comprises a multi-core stranded wire, a flexible printed circuit, or a coaxial cable, which is electrically connected to the tester with one end thereof, and is electrically connected to a corresponding signal pin with another end thereof.

18. The probe card of claim 10, wherein the matching part comprises a multi-core stranded wire, a flexible printed circuit, or a coaxial cable, which is electrically connected to the tester with one end thereof, and is electrically connected to a corresponding signal pin with another end thereof.

19. The probe card of claim 8, wherein the predetermined percentage error is 10%.
